(19) United States
(12) Patent Application Publication
(10) Pub. No.: US 2009/0028671 A1
(43) Pub. Date: Jan. 29, 2009

(54) IN-LINE SYSTEM AND METHOD FOR MANUFACTURING A SEMICONDUCTOR PACKAGE

(75) Inventors: Ho-Tae Jin, Chungcheongnam-do (KR); Young-Seok Jung, Chungcheongnam-do (KR); Bong-Su Cho, Chungcheongnam-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/943,046

(22) Filed: Nov. 20, 2007

(30) Foreign Application Priority Data
Dec. 15, 2006 (KR) 2006-0128930

(51) Int. Cl. H01L 21/677; H01L 21/67

(52) U.S. Cl. 414/217; 414/222.13; 414/805; 901/27

(57) ABSTRACT

An in-line system for manufacturing a semiconductor package according to principles of the present invention can prevent wafer warpage due to a back-lap process and die defects due to sticking of the die. In one embodiment, the in-line system adheres a semiconductor chip to a substrate by coating a liquid adhesive agent on a rear surface of the wafer. The processes of the in-line system are preferably performed in series. More particularly, the in-line system for manufacturing a semiconductor package can include a loading unit for loading a wafer into the system. A back-lap unit can include a grinder configured to back-grind a rear surface of the wafer received from the loading unit. A cleansing unit preferably comprises an air pressure plasma generating unit for cleansing the wafer using air pressure plasma. A coating unit can be configured to form an adhesive layer on a rear surface of the cleansed wafer by using a nozzle to coat a liquid adhesive agent onto the wafer. In the coating unit, the wafer can be rotated or not rotated depending on the desired characteristics of the adhesive layer. An attaching unit is preferably provided to attach a dicing tape on the adhesive layer formed. And an unloading unit unloads the wafer from the system. A transporting unit can be configured to transport the wafer sequentially between the loading unit, the back-lap unit, the cleansing unit, the coating unit, the attaching unit, and the unloading unit. One or more wafer chucks can be mounted to the wafer as the wafer is transported through the manufacturing processes.

### CROSS-REFERENCE TO RELATED PATENT APPLICATION

This application claims the benefit of Korean Patent Application No. 10-2006-0128930, filed on Dec. 15, 2006, in the Korean Intellectual Property Office, the disclosure of which is incorporated herein by reference in its entirety.

### BACKGROUND OF THE INVENTION

1. Field of the Invention

The present invention relates generally to semiconductor package manufacturing systems and methods, and more particularly, to a system and method for manufacturing a semiconductor package, wherein a plurality of processes are performed on a wafer.

2. Description of the Related Art

After an integration process is finished, a semiconductor chip undergoes a packaging process for physically protecting the semiconductor chip from external environments and for providing external electrical connections to the semiconductor chip. The semiconductor packaging process is generally as follows. After devices are formed on one side of a wafer (called the “front surface” of the wafer), the other side (or “back surface”) of the wafer is back-lapped (or back-grinded). The wafer is then diced to separate it into individual semiconductor chips to be attached to a substrate (die attaching). In some cases, other semiconductor chips are then stacked on a top surface and/or a rear surface of the semiconductor chip attached to the substrate. Next, each semiconductor chip is electrically connected to the substrate by wire-bonding. A molding process, a solder ball attaching process, a marking process, and a testing process are then performed to finalize the semiconductor device. When necessary, a cleansing process can be performed between the above processes.

To minimize the size of the semiconductor package, the thickness thereof is reduced by performing a back-lap process on a rear surface of a wafer. As explained above, the back-lap process is performed before a dicing tape attaching process when the semiconductor package is assembled. A grinding process is typically used to perform the back-lap process in a progressive semiconductor packaging assembling process for a multi chip package (MCP), a double die package (DDP), a very-very thin profile small out-line package (TSOP), and an ultra thin small out-line package (USOP).

In general, the back-lap process reduces the thickness of the wafer, for example, from 200 μm or greater to 100 μm or smaller. Unfortunately, in many cases, because the wafer becomes so thin, wafer warpage occurs. Accordingly, it may become difficult to transport the wafer between assembling machines or to handle the wafer in the machines.

FIGS. 1A and 1B are photographs illustrating wafers having a reduced thickness and suffering from warpage as a result of a back-lap process. The wafer shown in FIG. 1A has a thickness of about 80 μm, and the wafer shown in FIG. 1B has a thickness of about 65 μm. As can be seen from FIGS. 1A and 1B, wafer warpage is more severe when the wafer thickness is smaller. Wafer warpage results in tensile or compressive stresses which may act in each of the semiconductor chips to deteriorate device performance. In addition, the warped wafer may be damaged while being manipulated. Accordingly, it would be desirable to prevent wafer warpage after the back-lap process at least until the die attaching process is performed.

After the back-lap process and before performing a dicing process, an adhesive layer is formed on a rear surface of the wafer, that is, on the grinded surface. In a conventional method of forming an adhesive layer, a sheet of die attach tape (DAF) is compressed onto a rear surface of a wafer. FIG. 2 is a photograph showing a DAF metamorphosed around a die and remaining attached to the die after performing a dicing process according to the conventional art. Referring to FIG. 2, the DAF is metamorphosed in portion “a” due to dicing and remains attached to the die in portion “b.” More specifically, the DAF is metamorphosed by heat generated during the dicing process, and thereafter remains attached to the wafer in a quantity larger than is needed.

FIG. 3 is a photograph showing a crack generated when a die to which a DAF is attached is separated according to the conventional art. Referring to FIG. 3, a crack “cc” is formed across a plurality of devices “aa” and bonding pads “bb.” As the wafer becomes thinner the amount of shear stress that the wafer can stand is reduced and may be less than the adhesive force of the DAF adhered by metamorphosis. In such instances, the semiconductor chip may be damaged when each of the semiconductor chips is separated.

Also, since the DAF is metamorphosed in the dicing process, the DAF may not be separated from some portions of the die. FIG. 4 is a schematic cross-sectional side view of a semiconductor wafer illustrating an adhesive defect that may be generated during die separation due to the sticking of the DAF according to the conventional art.

Referring to FIG. 4, the dicing process includes using a saw blade or a laser to cut from a front surface of a wafer 1, through a DAF 2, to a predetermined depth in a base layer 4. In the cutting process, a component of an adhesive agent 3 contained in the DAF 2 is heated locally and melted along the cutting line. The adhesive agent 3 may therefore become stuck on a wafer chip 5 between the DAF 2 and the cut section of the base layer 4. Accordingly, during a pick up process, when the diced wafer chip 5 is separated by a vacuum pad 6 and a pickup needle 7, separation of an edge portion of the wafer chip 5 is hampered by the stuck portion 8 of the adhesive agent 3. Tension stress is thereby generated due to the warpage of the wafer chip 5. As a result of the tensile stress, the wafer chip 5 is bent and the edge portion of the wafer chip 5 may be damaged.

A wafer chip which has undergone a rear surface back-lap process may have a thickness of between about 50 through 100 μm. As explained, a wafer this thin may bend and, in addition, frequently suffers from problems due to the use of the DAF. These problems may damage the die or deteriorate the device performance, thereby reducing both manufacturing yield and product reliability. Furthermore, the DAF is relatively expensive and thus increases the manufacturing costs.

### SUMMARY OF THE INVENTION

According to principles of the present invention, an in-line system for manufacturing a semiconductor package is provided, wherein the manufacturing processes are performed in a continuous process. More particularly, the manufacturing processes from the back-lap process to a process immediately before dicing are preferably performed sequentially in a continuous process to prevent warpage of the wafer and to further prevent die defects due to sticking of the die. In this process, a semiconductor chip can be adhered to a substrate by forming an adhesive material by a coating a liquid adhesive agent on a rear surface of the wafer.

The principles of the present invention also enable a method for manufacturing a semiconductor package in which the manufacturing processes from a back-lap process to a process before a dicing process can be performed in a continuous sequence.

According to one embodiment of the present invention, an in-line system for manufacturing a semiconductor package includes a loading unit configured to load a wafer into the system. The wafer is transported from the loading unit to a back-lap unit that grinds a rear surface of the wafer using a grinder. After grinding in the back-lap unit, a cleansing unit, which includes an air pressure plasma generating unit, cleanses the wafer using air pressure plasma. A coating unit then forms an adhesive layer on the cleansed rear surface of the wafer by using a nozzle to coat the wafer surface with a liquid adhesive agent. In various embodiments, this can be done either with or without rotating the wafer. An attaching unit next preferably attaches a dicing tape on the adhesive layer. Finally, an unloading unit unloads the wafer. A transporting unit is also preferably provided to transport the wafer sequentially from the loading unit to the back-lap unit, from the back-lap unit to the cleansing unit, from the cleansing unit to the coating unit, from the coating unit to the attaching unit, and from the attaching unit to the unloading unit.

An in-line system for manufacturing a semiconductor package embodying additional principles of the present invention may further include a vacuum absorption unit that receives a wafer from the coating unit and removes bubbles formed in the adhesive layer using a vacuum. A hardening unit can also be provided to receive the wafer from the vacuum absorption unit and harden the adhesive layer. In this embodiment, the transporting unit preferably passes the wafer from the coating unit to the vacuum absorption unit and the hardening unit and then to the unloading unit in series.

The transporting unit may include first and second discrete transporting members and a first continuous transporting member. The first discrete transporting member is preferably configured to transport the wafer from the loading unit to the back-lap unit, while the second discrete transporting member preferably transports the wafer from the back-lap unit to the cleansing unit. The first continuous transporting member preferably transports the wafer from the cleansing unit to the coating unit, the attaching unit, and the unloading unit in series. The first and second discrete transporting members may, for instance, comprise a robot arm. The first continuous transporting member may, for instance, comprise a conveyor belt.

According to an additional embodiment incorporating principles of the present invention, an in-line system for manufacturing a semiconductor package includes a loading unit, a back-lap unit, a cleansing unit, a coating unit, a vacuum absorption unit, a hardening unit, an attaching unit, and an unloading unit arranged in series. The loading unit is preferably configured to load a wafer into the system. The back-lap unit receives the wafer from the loading unit and back-grinds a rear surface of the wafer using a grinder. The back-lap unit may include a plurality of grinders. After grinding in the back-lap unit, the wafer may have a thickness of between about 20 to 200 μm.

After grinding in the back-lap unit, the cleansing unit, comprising an air pressure plasma generating unit, cleanses the wafer using air pressure plasma. The cleansing unit may generate plasma using a reaction gas selected from the group including oxygen, nitrogen, argon, methane, helium, carbon dioxide, or a mixture thereof.

The coating unit then forms an adhesive layer on the cleansed rear surface of the wafer by coating the rear surface with a liquid adhesive agent using a nozzle, in this case without rotating the wafer. The nozzle may drop the liquid adhesive agent onto the wafer in droplets and may coat the liquid adhesive agent while the nozzle is being moved. The nozzle may, for instance, comprise a slit, and a plurality of nozzles may be provided. The liquid adhesive agent may be selected from a group including an epoxy-group, an acryl group, a polyimide group, a silicon group, or it may be a mixture of any of these or similar groups. The liquid adhesive agent may have a viscosity in the range of between about 50 through 50000 cps. The adhesive layer may have a thickness of between about 2 to 100 μm.

The vacuum absorption unit next removes bubbles in the adhesive layer formed on the wafer. And a hardening unit then hardens the adhesive layer coated on the wafer. The hardening unit may harden the liquid adhesive agent using heat, an infrared ray, an ultraviolet ray, a microwave, or any combination of the above or other hardening methods. The attaching unit attaches a dicing tape on the adhesive layer. Finally, the unloading unit unloads the wafer from the system.

A transporting unit is also preferably provided to transport the wafer sequentially from the loading unit to the back-lap unit, the cleansing unit, the coating unit, the vacuum absorption unit, the hardening unit, the attaching unit, and the unloading unit in series. The transporting unit may include a first discrete transporting member configured to transport the wafer from the loading unit to the back-lap unit and a second discrete transporting member configured to transport the wafer from the back-lap unit to the cleansing unit. A first continuous transporting member can further be provided to transport the wafer through the cleansing unit. A third discrete transporting member can transport the wafer from the cleansing unit to the coating unit, while a fourth discrete transporting member can transport the wafer from the coating unit to the vacuum absorption unit. And a second continuous transporting member can transport the wafer through the vacuum absorption unit, the hardening unit, and the attaching unit to the unloading unit.

The first through fourth discrete transporting members may be provided by one or more robot arms. The first and second continuous transporting members may be conveyor belts. The wafer is preferably transported while the wafer is attached to a wafer chuck. The wafer chuck can, for instance, be a porous wafer chuck or a non-contact transporting Bernoulli wafer chuck.

According to another aspect of the present invention, a method of manufacturing a semiconductor package is provided. The method may include loading a wafer into an in-line system using a loading unit and transporting the wafer to a back-lap unit. The method preferably further includes grinding a rear surface of the wafer using a back-lap unit. The wafer can then be cleansed using air pressure plasma by a cleansing unit that includes an air pressure plasma generating unit. An adhesive layer can be formed on the wafer by coating a liquid adhesive agent on the rear surface of the wafer. A dicing tape can be attached on the adhesive layer, and the wafer can then be unloaded from the system. The wafer is preferably transported between the loading unit, the back-lap unit, the cleansing unit, the coating unit, the attaching unit, and the unloading unit in sequence using a transporting unit.

A plurality of transporting operations may be performed. A first discrete transporting member can transport the wafer from the loading unit to the back-lap unit. The wafer can then be transported by a second discrete transporting member from the back-lap unit to the cleansing unit. The wafer can further be sequentially transferred from the cleansing unit to the coating unit, the attaching unit, and the unloading unit using a first continuous transporting member.

Between the forming of the adhesive layer and the attaching of the dicing tape, the method may further include receiving the wafer into a vacuum absorption unit and removing bubbles in the adhesive layer using a vacuum. The method may also include receiving the wafer transported from the vacuum absorption unit into a hardening unit and hardening the adhesive layer. In this case, an additional plurality of transporting operations can be provided. For instance, the wafer can be sequentially transported between a coating unit that forms the adhesive layer, the vacuum absorption unit, the hardening unit, and the attaching unit.

### BRIEF DESCRIPTION OF THE DRAWINGS

The above and other features and advantages of the present invention will become more readily apparent through the following detailed description of various exemplary embodiments thereof, made with reference to the attached drawings, in which:

FIGS. 1A and 1B are photographs of conventional thin wafers showing warpage due to a back-lap process;

FIG. 2 is a photograph of a conventional die showing a die attaching tape (DAF) metamorphosed around and stuck to the die after performing a dicing process;

FIG. 3 is a photograph of a conventional die showing a crack generated when the die to which the DAF is attached is separated;

FIG. 4 is a schematic cross-sectional side view of a conventional die illustrating an adhesive defect that may be generated during die separation due to the sticking of the DAF;

FIG. 5 is a block diagram illustrating an in-line system for manufacturing a semiconductor package according to an embodiment of the present invention;

FIGS. 6A through 6H are schematic cross-sectional side views of a semiconductor wafer illustrating various steps in a semiconductor packaging process according to further principles of the present invention;

FIGS. 7A and 7B are schematic block diagrams of various potential embodiments of a transporting unit for use in the in-line system of FIG. 5; and

FIGS. 8A through 8C are schematic cross-sectional side views of a semiconductor wafer in a coating unit illustrating various potential embodiments of a nozzle in the coating unit of the in-line system in FIG. 5.

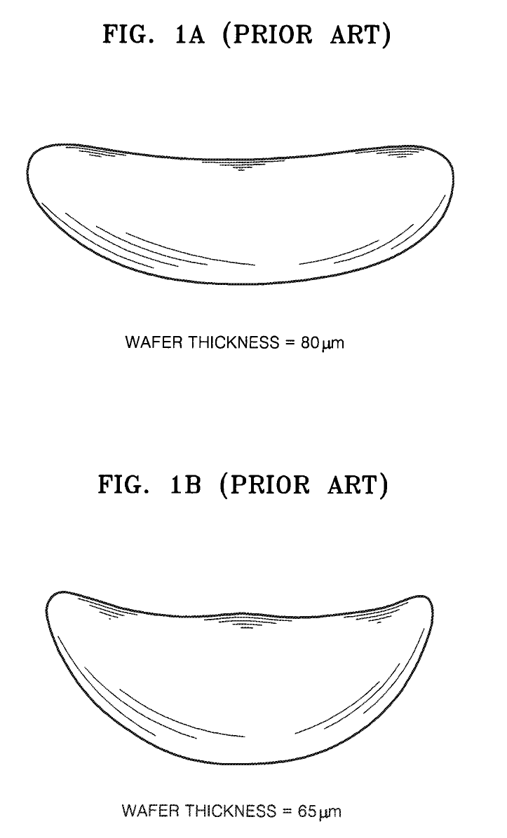

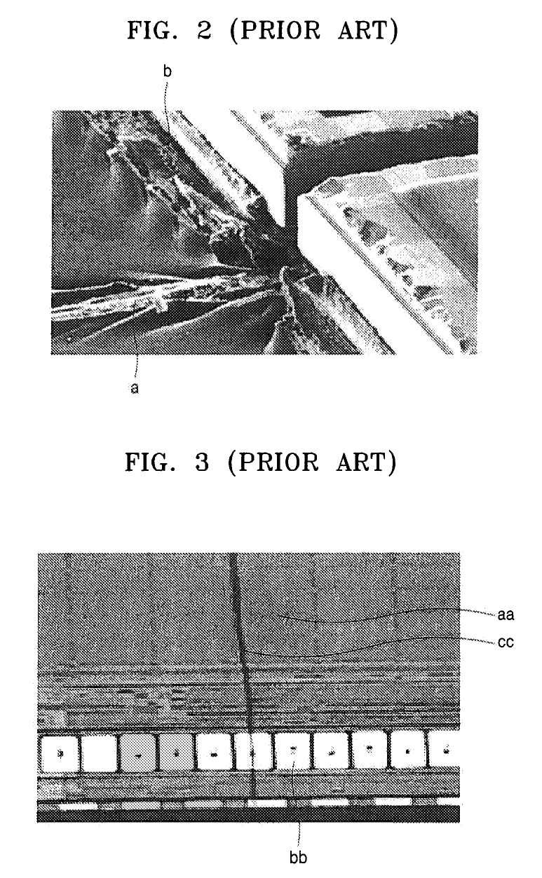

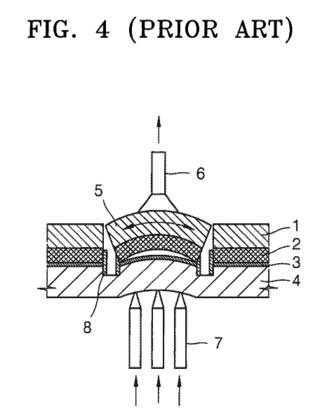

### DETAILED DESCRIPTION OF THE INVENTION

Principles of the present invention will now be described more fully with reference to the accompanying drawings, in which various exemplary embodiments of the invention are shown. It should be noted, however, that the invention may be embodied in many different forms and should not be construed as being limited to the specific embodiments set forth herein. Rather, these embodiments are provided to satisfy the enablement and best mode requirements by fully conveying the principles of the invention to those skilled in the art. In the following description, when a layer is referred to as being “on” another layer or substrate, it can be directly on the other layer or substrate, or intervening layers may also be present. In the drawings, the thicknesses of layers and regions may be exaggerated for clarity. Like reference numerals denote like elements, and duplicate descriptions may be omitted.

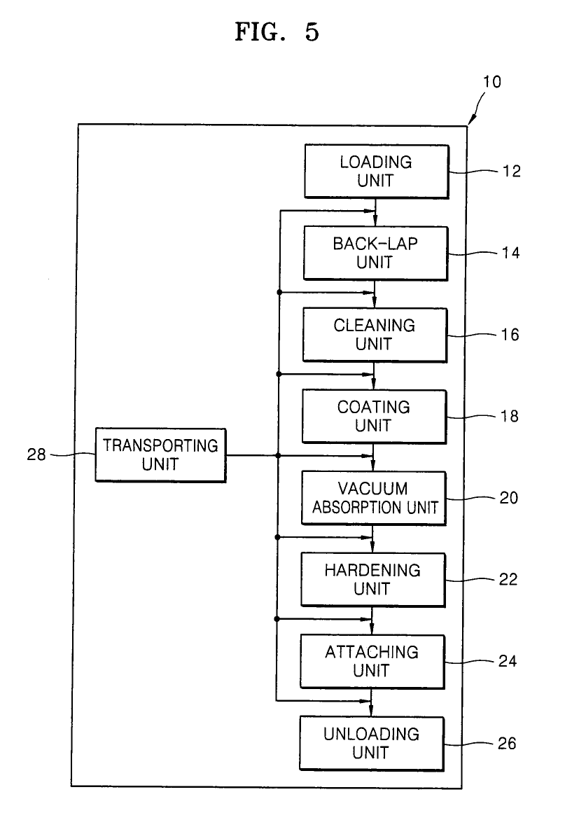

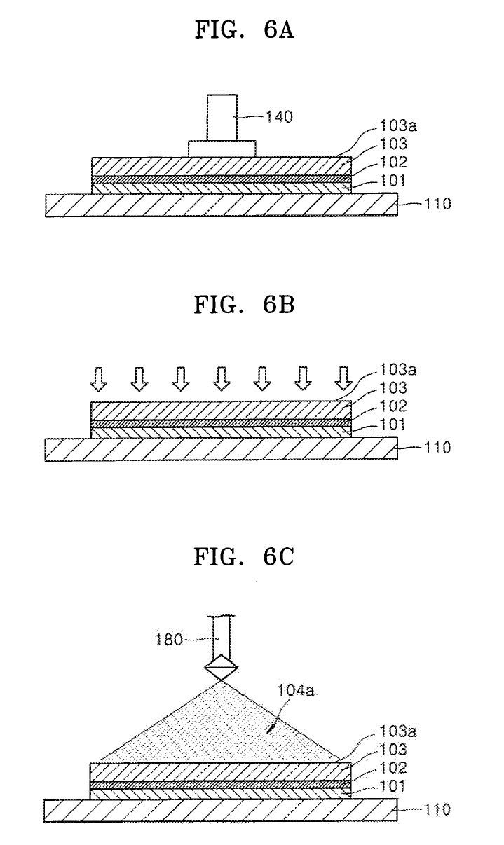

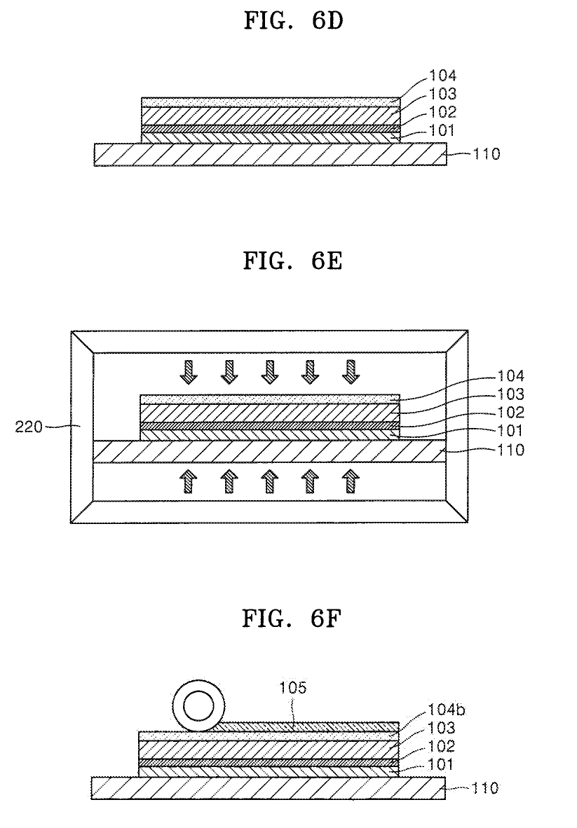

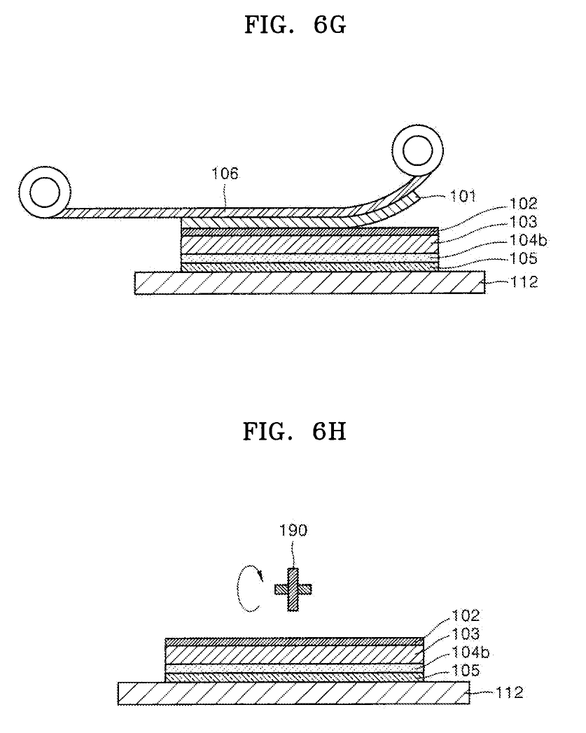

FIG. 5 is a block diagram illustrating an in-line system 10 for manufacturing a semiconductor package according to an embodiment of the present invention. FIGS. 6A through 6H are cross-sectional side views of the semiconductor wafer arranged in the in-line system 10, illustrating the steps of a semiconductor packaging method according to another aspect of the present invention. The various components of the in-line system 10 will be described in detail along with a description of the process of manufacturing a semiconductor package.

Referring first to FIG. 5, the in-line system 10 preferably includes a loading unit 12, a back-lap unit 14, a cleansing unit 16, a coating unit 18, an attaching unit 24, an unloading unit 26, and a transporting unit 28. The in-line system 10 may further include a vacuum absorption unit 20 and a hardening unit 22. Each unit in the in-line system 10 may be a separate apparatus or multiple units may be combined together. Alternatively, the in-line system 10 may be configured as a single apparatus.

Referring to FIG. 5, the loading unit 12 preferably loads a wafer 103 into the back-lap unit 14 of the in-line system 10. To prevent warpage of the wafer 103 due to its small thickness during each unit process in the in-line system 10, the wafer 103 is preferably fixed to a wafer chuck 110 before loading the wafer 103. The wafer 103 may, for instance, be fixed to the wafer chuck 110 using an adhesive agent such as an adhesive tape, using a conventional vacuum absorption method, or using a porous wafer chuck or a non-contact transporting Bernoulli wafer chuck. Of course, these are only a few possible examples and the present invention is not limited thereto. Hereinafter, the wafer chuck 110 and attached wafer 103 are transported together and, for convenience, will simply be referred to as transporting of the wafer 103

Referring now to FIGS. 5 and 6A, the semiconductor wafer is placed in the in-line system 10 with a rear surface 103a of the wafer facing upward. The rear surface 103a refers to a surface opposite a surface on which a device layer 102 and a back-lap tape 101 are placed. The back-lap tape 101 is attached on the device layer 102 and prevents contamination of the device layer 102. The back-lap tape 101 also protects the device layer 102 from external shock during the package manufacturing process, including the back-lap process.

The back-lap unit 14 preferably grinds the rear surface 103a of the wafer 103 to a desired thickness using a grinder 140. The back-lap unit 14 can include a driving member (not shown) and can perform a back-lap process using the driving member to rotate either the grinder 140 or the wafer chuck 110 and the attached wafer 103. To facilitate improved process flow of the in-line system 10 according to the current embodiment of the present invention, the back-lap unit 14 may include a plurality of grinders 140 to simultaneously grind a plurality of wafers 103. After grinding, the wafer 103 may, for instance, have a thickness of between about 20 to 200 μm.

Referring to FIGS. 5 and 6B, after the wafer 103 has been grinded, the wafer 103 (while remaining attached to the wafer chuck 110) is transported to the cleansing unit 16 using the transporting unit 28. As will be described in more detail later, the transporting unit 28 may, for instance, include a robot arm, a conveyor belt, or both The cleansing unit 16 can include a conventional air pressure plasma generating unit (not shown) that cleanses the rear surface 103a of the wafer 103 using air pressure plasma. The plurality of arrows in FIG. 6B denote plasma flow to the wafer 103.

A conventional air pressure plasma generating unit generates plasma by applying high voltage to a reaction gas such as oxygen, nitrogen, argon, methane, helium, carbon dioxide, or a mixture of these gases. Unlike a vacuum plasma generating unit, which requires a vacuum chamber, the conventional air pressure plasma generating unit does not require a sealed chamber Accordingly, by using the air pressure plasma generating unit in the cleansing unit 16, the wafer 103 can be cleansed while being transported continuously by the transporting unit 28, which may, for instance, be a conveyor belt.

Referring now to FIGS. 5, 6C and 6D, after the cleansing process, the wafer 103 is transported to the coating unit 18 by the transporting unit 28. The coating unit 18 can include a nozzle 180 that coats a liquid adhesive agent 104a onto the grinded rear surface 103a of the wafer 103 to form an adhesive layer 104. The liquid adhesive agent 104a may be coated, for instance, using a spin coating method, a spray coating method, or a line coating method. By using one of these coating methods, the coating unit 18 can coat the liquid adhesive agent 104a while rotating the wafer 103. It should be noted, however, that these are only a few possible examples and the present invention is not limited thereto. In particular, various embodiments may include a coating unit 18 in which the wafer 103 is not rotated. The coating unit 18 and the liquid adhesive agent 104a will be described in more detail below.

Referring again to FIG. 5, the wafer 103 on which the adhesive layer 104 is formed can then be transported to one or both of the vacuum absorption unit 20 and the hardening unit 22 using the transporting unit 28. The vacuum absorption unit 20 and the hardening unit 22 can be used to perform a vacuum absorption operation and a hardening operation, respectively. These are optional processes however, and, depending on the characteristics of the liquid adhesive agent and the desired properties of the adhesive layer, one or both of these operations may not be performed.

In operation, the vacuum absorption unit 20 removes minute air voids remaining in the adhesive layer 104 using a vacuum. The vacuum can be generated using a vacuum pump (not shown), and may be any appropriate vacuum. For instance, a low-suction vacuum of between about 10 to 10−2 Torr may be used to ensure that the adhesive layer 104 is not damaged by the vacuum. It should be obvious to one of ordinary skill in the art that there are differences in types of vacuum equipment, including the power of the vacuum pump for obtaining the desired vacuum force. Of course, the above example is illustrative only and the present invention is not limited thereto. Transportation of the wafer 103 to the vacuum absorption unit 20 will be described in more detail below.

Referring now to FIGS. 5, 6E and 6F, the hardening unit 22 can be used to harden the adhesive layer 104 in a hardening chamber 220 to form a hardened adhesive layer 104b. The hardening process hardens the adhesive layer 104 by removing a solvent from the liquid adhesive agent and can be performed to better enable subsequent processes such as a dicing tape attaching process and a dicing process. The hardness level of the hardened adhesive layer 104b can be generally referred to as a B-stage hardness level, where the B-stage is in an intermediate state between a liquid state (referred to as an A-stage) and a completely hardened solid state (referred to as a C-stage). The hardening chamber 220 may additionally be designed to function as a vacuum chamber of the vacuum absorption unit 20.

The energy source for performing the hardening operation may, for instance, be heat, infrared rays, ultraviolet rays, or microwaves. These are merely illustrative examples, however, and the present invention is not limited thereto. For example, the adhesive layer 104 may be sprayed with dry air or may be further coated with a hardening agent to harden the adhesive layer 104.

When heat energy (such as from a conventional oven) is used for hardening, the equipment is simple and inexpensive. Unfortunately, however, it may also take longer (i.e., several tens of minutes) to harden the adhesive layer 104, thus increasing the processing costs. Also, because it is hardened by heat from the surface, heat may accumulate inside the adhesive layer 104 and bubbles from inside may expand and generate unevenness such as craters in the surface of the adhesive layer 104, thereby decreasing the quality of the adhesive layer 104. Furthermore, the back-lap tape 101 may be thermally damaged, which may damage the device layer 102.

When infrared or ultraviolet rays are used for hardening, the temperature on the surface and inside the adhesive layer 104 can be increased uniformly to prevent quality deterioration due to thermal shock to the adhesive layer 104. Also, since infrared radiation can generally complete the hardening process in a matter of minutes, the processing time is relatively short. However, to use these methods, the adhesive layer 104 needs to be formed of a material that can be heated by absorbing infrared or ultraviolet rays.

A microwave is an electromagnetic wave having a frequency of between about 0.3 to 300 GHz. When microwaves are radiated to a medium, the microwave may be reflected (if the medium is metal), transmitted (if the medium has non-polarity), or absorbed (if the medium has polarity). Therefore, when a material has polarity, a microwave is absorbed into and increases the temperature of the material. At an atomic level, in a material having polarity certain atoms respond to the microwaves and increase their movement, thereby heating the material. In water, for example, the hydrogen atoms maintain bonding with oxygen atoms while increasing their rotational or oscillation movement around the oxygen atoms, and thus the temperature of the material is raised.

Accordingly, when the adhesive layer 104 is hardened using microwaves, the liquid adhesive agent forming the adhesive layer 104 should contain a material having polarity. Most preferably, the material having polarity should be uniformly distributed throughout the liquid adhesive agent. Also, since the absorption depth of the microwave is inversely proportional to the frequency of the microwave, the frequency of the microwave should be determined based on the thickness of the adhesive layer 104. In addition, as devices formed in the device layer 102 are likely to be damaged by the microwave reflected by metal, such as that in the wafer chuck 110, appropriate measures such as grounding need to be taken.

When microwaves are used for hardening, the surface and inside of the adhesive layer 104 can be uniformly hardened, and the hardening time can be reduced. Unfortunately, however, the equipment for performing microwave hardening can be relatively difficult to use and it may therefore be difficult to control the hardening process to obtain uniform hardening. The adhesive layer 104 must further be formed of a material that will absorb the microwaves.

Referring to FIGS. 5 and 6F, when the hardening of the adhesive layer 104 is finished, or if the vacuum absorption and/or hardening processes are not performed, then after the preceding process, the wafer 103 is preferably transported to the attaching unit 24 by the transporting unit 28. In the attaching unit 24, conventional dicing tape 105 can be attached to the hardened adhesive layer 104b. The dicing tape 105 is preferably attached so that each die, including the adhesive layer 104, is distinctively separated through a subsequent dicing process while ensuring that a stage 112 (see FIG. 6G) below the wafer 103 is not damaged by a saw 190 (see FIG. 6H). The dicing tape 105 may be formed of the same material as the previously-described back-lap tape 101.

Referring back to FIG. 5, the wafer 103 is next transported to the unloading unit 26 by the transporting unit 28. The unloading unit 26 preferably unloads the wafer 103 from the in-line system 10 to an external environment. The wafer 103 can be unloaded by mounting the wafer 103 on a conventional magazine to be transported to a subsequent process. Here, attention should be given to unload the wafer 103 while it remains fixed in the wafer chuck 110 to prevent warpage of the wafer 103.

FIGS. 6G and 6H illustrate subsequent processes that may be performed after the wafer 103 is unloaded from the in-line system 10. Referring to FIG. 6G, the wafer 103 with the attached dicing tape 105 can be turned over and positioned on the stage 112 with the back-lap tape 101 directed upwardly. To prevent warpage of the wafer 103, the stage 112 is preferably fixed to the wafer 103 by vacuum absorption or comprises a porous wafer chuck to fix the wafer 103. Alternatively, an adhesive layer may be formed on the dicing tape 105 to fix the wafer 103 to the stage 112. The back-lap tape 101 can then be removed from the fixed wafer 103 using a removing tape 106. The device layer 102 on the top surface of the wafer 103 is thereby exposed.

Referring to FIG. 6H, a saw 190 can then be used to cut the device layer 102, the wafer 103, and the die attaching layer 104b to form a die. The separated dies can then be processed in a subsequent packaging process to form semiconductor packages. A detailed description of conventional processes will be omitted but will be readily understood by those skilled in the art.

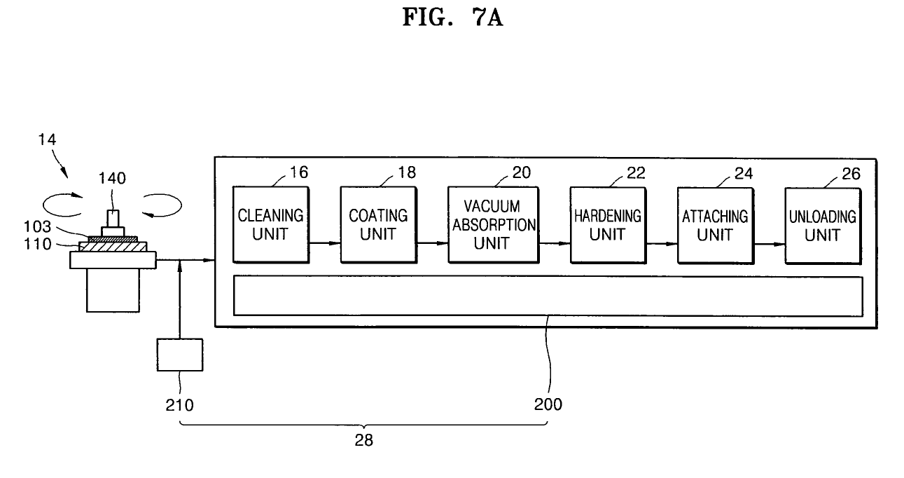

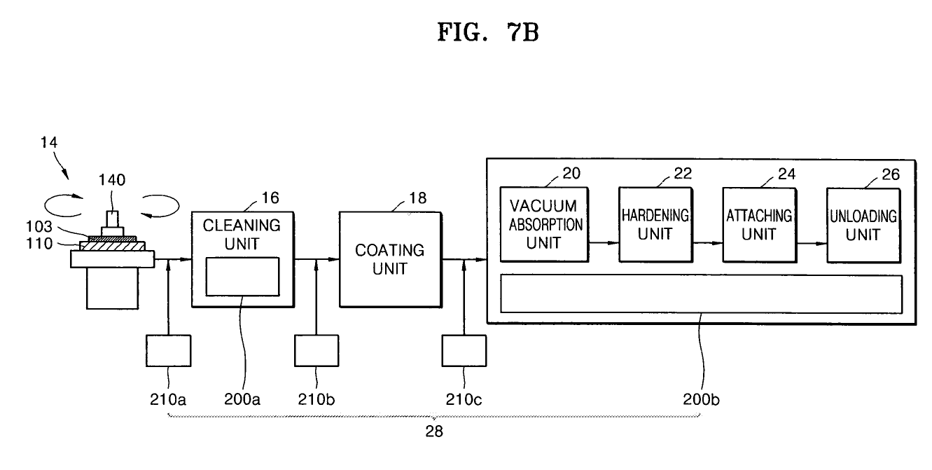

The construction and operation of the transporting unit 28 will now be described in greater detail. As previously described, one desirable characteristic of the in-line system 10 constructed and operated according to principles of the present invention is that the processes can be performed while the wafer 103 is being continuously transported from the loading unit 12 to the unloading unit 26. Accordingly, the specific equipment used by the transporting unit 28 to transport the wafer may be varied depending on the processes. In the in-line system 10, the wafer 103 is preferably moved continuously and linearly, but may be rotated, for instance, in the back-lap unit 14 and in the coating unit 18. Various aspects and embodiments of the transporting unit 28, which correspond to respective processing conditions of the above-described emit processes, will now be described in further detail with reference to FIGS. 7A and 7B.

FIGS. 7A and 7B illustrate various examples of the transporting unit 28 as may be used in the in-line system 10 of FIG. 5. In each example shown, the transporting unit 28 preferably includes at least one continuous transporting member 200 and at least one discrete transporting member 210. These are only examples, however, and are not limiting of the present invention.

Referring first to FIG. 7A, the wafer 103 attached to the wafer chuck 110 is transported by the loading unit 102 to the back-lap unit 14. The wafer 103 can, for instance, be transported using a conventional robot arm. As the grinding process is performed in the back-lap unit 14, the wafer 103 or the grinder 140 can be rotated. A processing time, in which the wafer 103 is not transported in the back-lap unit 14, is therefore required to perform this process. Accordingly, this process may delay the entire process flow of the in-line system 10. The back-lap unit 14 can therefore include a plurality of grinders 140 to simultaneously grind a plurality of wafers 103.

After grinding is completed in the back-lap unit 14, the wafer 103 is transported from the back-lap unit 14 to the cleansing unit 16. Since the wafer 103 is being transported after grinding is finished, discrete transportation is desirable. When a single wafer 103 is grinded at a time, the transporting unit 28 is not operated during grinding, but resumes operation after grinding is finished. In this specification, a transporting unit that enables such one-time transportation may be referred as a “discrete transporting member.” The wafer 103 is transported from the back-lap unit 14 to the cleansing unit 16 by a discrete transporting member 210. The discrete transporting member 210 may, for instance, be a conventional robot arm that picks up the wafer 103 together with the wafer chuck 110 from the stage of the back-lap unit 14 and transports them to the cleansing unit 16. This robot arm may be identical to a robot arm used in the loading unit 12.

Alternatively, the discrete transporting member 210 may include an additional wafer chuck. In this case, the additional wafer chuck sucks the wafer 103 from the upper portion of a grinded rear surface 103a of the wafer chuck 103 to separate the wafer chuck 110 and the wafer 103. The transporting member 210 then transports the wafer 103 to the cleansing unit 16. The wafer 103 can be attached to the additional wafer chuck, for instance, using vacuum absorption or using a porous wafer chuck. The additional wafer chuck may be attached to the wafer 103 continuously throughout the subsequent processes, including the cleansing unit 16 or the cleansing unit 16 may include yet another wafer chuck to receive the wafer 103 from the first additional wafer chuck. When the wafer 103 is transported in this manner, the wafer 103 should always be attached to one of the wafer chucks to prevent wafer warpage.

The wafer 103 can be continuously transported as the cleansing unit 16, the coating unit 18, the vacuum absorption unit 20, the hardening unit 22, the attaching unit 24, and the unloading unit 26 are operated in series. Continuous transportation can refer to transportation of the wafer 103 without stopping while each unit process is being performed. A transporting unit enabling such continuous transportation may be referred to herein as a “continuous transporting member.” Accordingly, the wafer 103 can be transported from the cleansing unit 16 to the unloading unit 26 using a continuous transporting member 200. The continuous transporting member 200 may, for instance, be a conveyor belt.

As described above, the cleansing unit 16 preferably includes an air pressure plasma generating unit that cleanses the wafer 103 using air pressure plasma. The air pressure plasma generating unit does not require vacuum equipment, and the wafer 103 can therefore be cleansed while being continuously transported through the air pressure plasma generating unit using the continuous transporting member 200. The air pressure plasma generating unit may further include a blocking wall (not shown) for preventing leakage of the air pressure plasma.

The wafer 103 can be continuously transported from the cleansing unit 16 to the coating unit 18 using the continuous transporting member 200. While the wafer 103 is being transported through the coating unit 18, a liquid adhesive agent 104a is coated onto the wafer to form an adhesive layer 104. When a continuous transporting member 200 is used during this process, the wafer 103 is preferably not rotated. This process will be described in further detail later on with respect to various possible coating methods.

The wafer 103 can further be continuously transported from the coating unit 18 to the vacuum absorption unit 20 using the continuous transporting member 200. As described above, the vacuum absorption unit 20 can optionally be used to remove bubbles formed in the adhesive layer 104. The vacuum absorption unit 20 may include a vacuum chamber having a blocking layer for forming a vacuum. Alternatively, a vacuum absorption process may be performed by connecting a conventional bellows or other absorption portion to the wafer 103 to provide the vacuum. Of course, these are examples only, and the present invention is not limited thereto.

After vacuum absorption, the wafer 103 is then preferably transported to the hardening unit 22 using the continuous transporting member 200. The hardening unit 22 can optionally be used to harden the adhesive layer 104. The wafer 103 can be continuously transported during the hardening process using the continuous transporting member 200. The wafer 103 is also preferably continuously transported to the attaching unit 24 and the unloading unit 26 using the continuous transporting member 200 to perform the additional processes therein.

The continuous transporting member 200 may include one or more continuous transporting members 200. For example, multiple conveyor belts may be connected to one another to transport the wafer 103. The process units 12, 14, 16, 18, 20, 22, 24, 26 may be arranged linearly in the in-line system 10, but the present invention is not limited to a linear system. For example, the unloading unit 26 may be arranged adjacent to the loading unit 12 such that the whole arrangement may be configured in a circular form.

FIG. 7B illustrates another possible configuration for the transporting unit 28 of the in-line system 10 of FIG. 5. Unlike the previous embodiment, in this configuration, the wafer 103 is preferably rotated while in the coating unit 18. Referring to FIG. 7B, after grinding in the back-lap unit 14 is finished, the wafer 103 is transported from the back-lap unit 14 to the cleansing unit 16 by a first discrete transporting member 210a. The first discrete transporting member 210a can be the same as the discrete transporting member 210 of FIG. 7A.

In the cleansing unit 16, the wafer 103 is preferably transported by the first continuous transporting member 200a and cleansed while being transported. When the cleansing process is finished, the wafer 103 is preferably transported to the coating unit 18 using a second discrete transporting member 210b. The second discrete transporting member 210b may be similar or identical to the first discrete transporting member 210a.

In the coating unit 18 of this embodiment, the wafer is preferably rotated while the liquid adhesive agent 104a is coated on the wafer 103 to form an adhesive layer 104. The coating unit 18 can include a conventional rotation member such as a rotation stage (not shown). The specific coating methods that may be used in the coating unit 18 where the wafer 103 is rotated will be described in further detail below. As with the back-lap unit 14, when the wafer 103 is being rotated, a processing time where the wafer 103 is not moved through the coating unit 18 is required. Accordingly, this processing time may delay the entire process flow of the in-line system 10. The coating unit 18 may therefore be designed to coat a plurality of wafers 103 at the same time.

When the coating operation is finished, the wafer 103 can then be transported to the vacuum absorption unit 20 using a third discrete transporting member 210c. The third discrete transporting member 210c may be similar or identical to the first and second discrete transporting members 210a, 210b.

The wafer 103 is then preferably transported from the vacuum absorption unit 20 through to the unloading unit 26 using a second continuous transporting member 200b. The second continuous transporting member 200b can be similar to the continuous transporting member 210 of FIG. 7A.

The various transporting units 28 described above are exemplary only and the principles of the present invention are not limited to these specific examples. One characteristic provided by certain principles of the present invention is that parts of the packaging processes may be performed continuously in the in-line system 10 as described above. To provide these benefits, the various components of the transporting unit 28 should be selected and combined in a manner that will optimize the arrangement. In addition, the transportation time should be selected to optimize each unit process. To simultaneously perform identical processes on a plurality of wafers 103 in all or part of the process, the plurality of wafers 103 may be arranged on the transporting unit 28. Alternatively, or in addition, a plurality of all or part of the processing units may be provided.

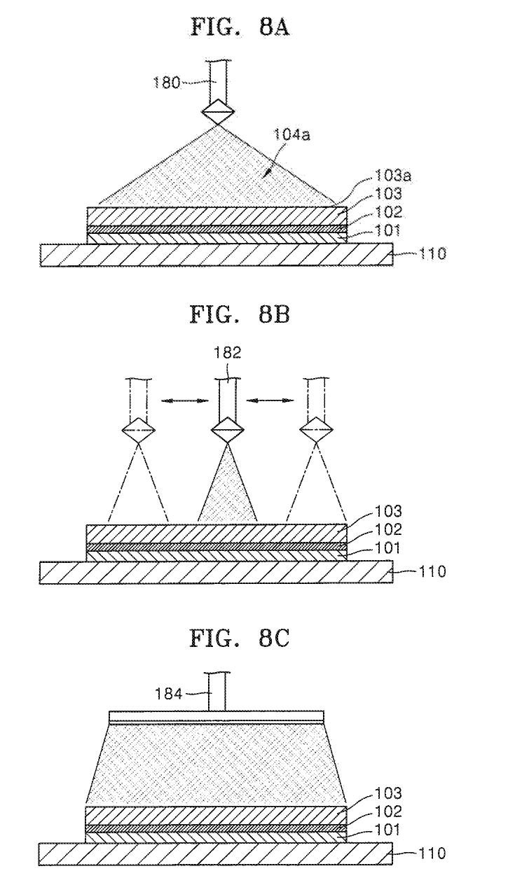

The coating process using the coating unit 18 will now be described in further detail with reference to FIGS. 8A through 8C, which illustrate various examples of a nozzle as used in the coating unit 18 of FIG. 5. Referring to FIG. 8A, the coating unit 18 coats the liquid adhesive agent 104a onto the wafer 103 mounted in the wafer chuck 110 using the nozzle 180. The liquid adhesive agent 104a is preferably non-conductive and has a predetermined viscosity. The liquid adhesive agent 104a is preferably applied such that it forms a small contact angle with the wafer 103 to be coated. The viscosity of the liquid adhesive agent 104a may, for example, be in the range of between about 50 through 50000 cps. In general, the lower the viscosity of the liquid adhesive agent 104a, the easier it is to form a thin adhesive layer 104. The thickness of the adhesive layer 104 formed by the liquid adhesive agent 104a is preferably between about 2 to 100 μm. The liquid adhesive agent may, for example, be an epoxy-group, an acryl group, a polyimide group, a silicone group, or any mixture of these groups or other similar groups.

As illustrated in FIG. 8A, the nozzle 180 may spray the liquid adhesive agent 104a over the entire rear surface 103a of the wafer 103 to coat the wafer 103. In this case, the wafer 103 can either be rotated or not rotated. Accordingly, with this nozzle configuration, the transporting unit may be constructed according to either of the embodiments described above with reference to FIGS. 7A and 7B. It should be noted, however, that the coating methods shown with respect to the nozzle 180 are illustrative only and the present invention is not limited thereto.

For example, the entire rear surface 103a could be coated by coating a predetermined region including the center of the rear surface 103a of the wafer 103 with the liquid adhesive agent 104a as the wafer 103 is being rotated. Alternatively, the nozzle 180 may coat the entire rear surface 103a by dropping the liquid adhesive agent 104a in droplets on the rear surface 103a while the wafer 103 is being rotated. These methods are generally referred to as “spin-coating.” When the wafer 103 is rotated, the wafer 103 should be mounted on a rotation stage (not shown) included in the coating unit 18, and the transporting unit 28 should be a structure such as that described with reference to FIG. 7B.

By rotating the wafer 103 during coating, the centrifugal force can cause the liquid adhesive agent 104a to form a more uniform adhesive layer 104 on the wafer The wafer 103 may be rotated either clockwise or counter-clockwise. The liquid adhesive agent 104a may be applied before, during, or after the wafer 103 is rotated. Also, after applying the liquid adhesive agent 104a, the rotation speed may be changed. To obtain a uniform coating of liquid adhesive agent 104a, the amount of liquid adhesive agent 104a applied to the wafer 103, the pressure during spraying, the distance between the nozzle 180 and the wafer 103, the rotation speed, the rotation time, and the rotation starting time of the wafer 103 are preferably determined in relation to the viscosity of the liquid adhesive agent 104a and the desired thickness of the adhesive layer 104 (e.g., preferably between 2 through 100 μm).

Referring to FIG. 8B, in an alternative embodiment, a nozzle 182 moves across the wafer 103 using a nozzle moving unit (not shown) to coat the wafer 103 with the liquid adhesive agent 104a. The wafer 103 may be rotated as described above. If the wafer 103 is rotated, the nozzle 182 can uniformly coat the wafer 103 by applying the liquid adhesive agent 104a to only a part of the wafer 103 that includes the center of the wafer 103. The nozzle 182 may be moved in various manners to provide a uniform coating of liquid adhesive agent 104a. The nozzle 182 may, for example, be moved in a radial direction toward the outer circumference from the center of the wafer 103, in an opposite direction from the circumference to the center of the wafer 103, or in zigzag direction. Alternatively, the nozzle 182 may be moved circularly around the wafer 103. The embodiment shown in FIG. 8B may be effective in forming a relatively thick adhesive layer 104.

Referring now to FIG. 8C, a nozzle 184 can coat the liquid adhesive agent 104a over a relatively wide region of the wafer 103 at one time. Specifically, if the wafer 103 is not rotated during coating, the diameter of the nozzle 184 (or, more particularly, the region to be coated by the nozzle 184) is preferably at least the same as the diameter of the wafer 103. The wafer 103 can optionally be rotated during coating with the nozzle 184. The nozzle 184 may be a slit or a plurality of nozzle holes that combine together to cover the width of the wafer 103.

The nozzle 184 of FIG. 8C may be effective in coating the wafer 103 with the adhesive agent 104a while transporting the wafer 103 using the continuous transporting member 200 described with reference to FIG. 7A. This embodiment may also be effective when the rotation speed is low or when the viscosity of the liquid adhesive agent 104a is too high or too low. This embodiment can also be used to effectively reduce the processing time. It should be noted, however, that each of the embodiments described with reference to FIGS. 8A through 8C are illustrative only and the present invention is not limited thereto.

In an in-line system for manufacturing a semiconductor package constructed according to principles of the present invention, the semiconductor manufacturing processes from a back-lap process to a process preceding a dicing process can be performed continuously. Thus, warpage of the wafer and die defects caused by die sticking can be effectively reduced or prevented. In addition, an adhesive layer can be formed by coating a liquid adhesive agent on a wafer for die adhesion, thereby preventing conventional damage of the wafer due to sticking of a die attaching tape. This can further reduce manufacturing costs associated with expensive die attaching tape. Furthermore, an adhesive force can be increased through an increase of wetness between a rear surface of the wafer and the adhesive agent when an air pressure plasma cleansing process and a vacuum absorption process are used. Blow defects that result after packaging assembly due to bubbles can also be reduced through these processes by limiting the occurrence of bubbles between the wafer and the liquid adhesive agent.

While the present invention has been shown and described with reference to various exemplary embodiments thereof, it will be understood by those of ordinary skill in the art that various changes in form and details may be made thereto without departing from the spirit and scope of the present invention as defined by the following claims.

What is claimed is:

1. An in-line system for manufacturing a semiconductor package, the system comprising:
a loading unit configured to load a wafer into the in-line system;
a back-lap unit configured to receive the wafer from the loading unit and to grind a rear surface of the wafer using a grinder;
a cleansing unit comprising an air pressure plasma generating unit, said cleansing unit configured to cleanse the rear surface of the wafer using air pressure plasma following grinding in the back-lap unit;
a coating unit configured to form an adhesive layer on the rear surface of the wafer that has been cleansed by the cleansing unit, wherein the coating unit is configured to coat a liquid adhesive agent onto the wafer using a nozzle;
an attaching unit configured to attach a dicing tape to the adhesive layer;
an unloading unit configured to unload the wafer; and
a transporting unit configured to transport the wafer sequentially between the loading unit, the back-lap unit, the cleansing unit, the coating unit, the attaching unit, and the unloading unit.

2. The in-line system of claim 1, wherein the transporting unit comprises:
a first discrete transporting member configured to transport the wafer from the loading unit to the back-lap unit;
a second discrete transporting member configured to transport the wafer from the back-lap unit to the cleansing unit; and
a first continuous transporting member configured to transport the wafer from the cleansing unit to the coating unit, the attaching unit, and the unloading unit in series.

3. The in-line system of claim 2, wherein the first and second discrete transporting members each comprise a robot arm.

4. The in-line system of claim 1, wherein the coating unit is configured to coat the wafer without rotating the wafer.

5. The in-line system of claim 2, wherein the transporting unit comprises a plurality of first discrete transporting members and a plurality of second discrete transporting members.

6. The in-line system of claim 2, wherein the first continuous transporting member comprises a conveyor belt.

7. The in-line system of claim 1, the system further comprising:
a vacuum absorption unit configured to receive the wafer from the coating unit and to remove bubbles in the adhesive layer using a vacuum; and
a hardening unit configured to receive the wafer from the vacuum absorption unit and to harden the adhesive layer,
wherein the transporting unit is configured to transport the wafer from the coating unit to the vacuum absorption unit, the hardening unit, and then to the unloading unit in series.

8. The in-line system of claim 7, wherein the transporting unit comprises a first continuous transporting member and a second continuous transporting member connected to the first continuous transporting member.

9. The in-line system of claim 8, wherein the second continuous transporting member comprises a conveyor belt.

10. The in-line system of claim 1, wherein the nozzle coats the liquid adhesive agent onto the wafer while the nozzle is being moved.

11. The in-line system of claim 1, wherein the nozzle comprises a slit.

12. The in-line system of claim 1, wherein the nozzle comprises a plurality of nozzles.

13. The in-line system of claim 1, wherein the wafer is configured to be transported while the wafer is attached to a wafer chuck.

14. The in-line system of claim 13, wherein the wafer chuck is a porous wafer chuck or a non-contact transporting Bernoulli wafer chuck.

15. The in-line system of claim 1, wherein the back-lap unit comprises a plurality of grinders.

16. The in-line system of claim 1, wherein after grinding in the back-lap unit, the wafer has a thickness of between about 20 to 200 μm.

17. The in-line system of claim 1, wherein the cleansing unit is configured to generate plasma using a reaction gas comprising one or more gases selected from the group consisting of: oxygen, nitrogen, argon, methane, helium, and carbon dioxide.

18. The in-line system of claim 1, wherein the liquid adhesive agent comprises one or more groups selected from a group consisting of: an epoxy-group, an acryl group, a polyimide group, and a silicon group.

19. The in-line system of claim 1, wherein the liquid adhesive agent has a viscosity in the range of between about 50 through 50000 cps.

20. The in-line system of claim 1, wherein the adhesive layer has a thickness of between about 2 to 100 μm.

21. The in-line system of claim 7, wherein the hardening unit is configured to harden the liquid adhesive agent using heat, infrared rays, ultraviolet rays, or microwaves.

22. An in-line system for manufacturing a semiconductor package, the system comprising:
a loading unit configured to load a wafer into the in-line system;
a back-lap unit configured to back-grind a rear surface of the wafer;
a cleansing unit comprising an air pressure plasma generating unit, said cleansing unit configured to cleanse the wafer using air pressure plasma after grinding in the back-lap unit;
a coating unit configured to form an adhesive layer on a rear surface of the wafer that has been cleansed by the cleansing unit, said coating unit configured to coat a liquid adhesive agent onto the wafer using a nozzle;
a vacuum absorption unit configured to use a vacuum to remove bubbles from the adhesive layer formed on the wafer in the coating unit;
a hardening unit configured to harden the adhesive layer;
an attaching unit configured to attach a dicing tape on the adhesive layer;
an unloading unit configured to unload the wafer; and
a transporting unit configured to transport the wafer sequentially between the loading unit, the back-lap unit, the cleansing unit, the coating unit, the vacuum absorption unit, the hardening unit, the attaching unit, and the unloading unit.

23. The in-line system of claim 22, wherein the transporting unit comprises:
a first discrete transporting member configured to transport the wafer from the loading unit to the back-lap unit;
a second discrete transporting member configured to transport the wafer from the back-lap unit to the cleansing unit;
a first continuous transporting member configured to transport the wafer in the cleansing unit;
a third discrete transporting member configured to transport the wafer from the cleansing unit to the coating unit;
a fourth discrete transporting member configured to transport the wafer from the coating unit to the vacuum absorption unit; and
a second continuous transporting member configured to transport the wafer between the vacuum absorption unit, the hardening unit, the attaching unit, and the unloading unit.

24. The in-line system of claim 23, wherein the first through fourth discrete transporting members each comprise a robot arm.

25. The in-line system of claim 23, wherein at least two of the first through fourth discrete transporting members are identical to one another.

26. The in-line system of claim 23, wherein a plurality of the first through fourth discrete transporting members are respectively comprised of a robot arm.

27. The in-line system of claim 23, wherein the first and second continuous transporting members each comprise a conveyor belt.

28. The in-line system of claim 22, wherein the nozzle is configured to drop the liquid adhesive agent in droplets onto the wafer.

29. The in-line system of claim 22, wherein the wafer is not rotated in the coating unit and wherein the nozzle coats the liquid adhesive agent onto the wafer while the nozzle is being moved.

30. The in-line system of claim 22, wherein the nozzle comprises a slit.

31. The in-line system of claim 22, wherein the nozzle comprises a plurality of nozzles.

32. The in-line system of claim 22, wherein the adhesive agent is coated onto the wafer while the wafer is being rotated.

33. The in-line system of claim 22, wherein the liquid adhesive agent is coated onto the wafer after the wafer is rotated.

34. The in-line system of claim 22, wherein the liquid adhesive agent is coated onto the wafer before the wafer is rotated.

35. The in-line system of claim 22, wherein the wafer is transported while the wafer is attached to a wafer chuck.

36. The in-line system of claim 35, wherein the wafer chuck is a porous wafer chuck or a non-contact transporting Bernoulli wafer chuck.

37. The in-line system of claim 22, wherein the back-lap unit comprises a plurality of grinders.

38. The in-line system of claim 22, wherein after the grinding in the back-lap unit, the wafer has a thickness of between about 20 to 200 μm.

39. The in-line system of claim 22, wherein the cleansing unit generates plasma using one or more reaction gases selected from the group consisting of: oxygen, nitrogen, argon, methane, helium, and carbon dioxide.

40. The in-line system of claim 22, wherein the liquid adhesive agent comprises one or more groups selected from the group consisting of: an epoxy-group, an acryl group, a polyimide group, and a silicon group.

41. The in-line system of claim 22, wherein the liquid adhesive agent has a viscosity in the range of between about 50 through 50000 cps.

42. The in-line system of claim 22, wherein the adhesive layer has a thickness of between about 2 to 100 μm.

43. The in-line system of claim 22, wherein the hardening unit hardens the liquid adhesive agent using heat, infrared rays, ultraviolet rays, or microwaves.

44. A method of manufacturing a semiconductor package, the method comprising:
loading a wafer into an in-line system using a loading unit;
grinding a rear surface of the wafer using a back-lap unit;
cleansing the wafer using air pressure plasma generated by an air pressure plasma generating unit arranged in a cleansing unit;
forming an adhesive layer by coating a liquid adhesive agent on the rear surface of the wafer using a coating unit;
attaching a dicing tape on the adhesive layer formed on the wafer using an attaching unit;
unloading the wafer from the in-line system using an unloading unit; and
sequentially transporting the wafer between the loading unit, the back-lap unit, the cleansing unit, the coating unit, the attaching unit, and the unloading unit using a transporting unit.

45. The method of claim 44, wherein sequentially transporting the wafer comprises:
transporting the wafer from the loading unit to the back-lap unit using a first discrete transporting member;
transporting the wafer from the back-lap unit to the cleansing unit using a second discrete transporting member; and
sequentially transporting the wafer from the cleansing unit to the coating unit, from the coating unit to the attaching unit, and from the attaching unit to the unloading unit using a first continuous transporting member.

46. The method of claim 44, further comprising:
removing bubbles in the adhesive layer using a vacuum absorption unit;
hardening the adhesive layer in a hardening unit; and
sequentially transporting the wafer between the coating unit and the vacuum absorption unit, between the vacuum absorption unit and the hardening unit; and between the hardening unit and the attaching unit.
